(19) United States
(12) Patent Application Publication
(10) Pub. No.: US 2025/0183568 A1
(43) Pub. Date: Jun. 5, 2025

(54) ELECTRONIC DEVICE

(71) Applicant: AISIN CORPORATION, Kariya-shi, Aichi (JP)

(72) Inventors: Shinsuke ANDO, Kariya-shi, Aichi-ken (JP); Yudai KINOSHITA, Kariya-shi, Aichi-ken (JP)

(73) Assignee: AISIN CORPORATION, Kariya-shi, Aichi (JP)

(21) Appl. No.: 18/842,294

(22) PCT Filed: May 18, 2023
(86) PCT No.: PCT/JP2023/018552

§ 371 Date: Aug. 28, 2024

(30) Foreign Application Priority Data
May 27, 2022 (JP) 2022-086796

(51) Int. Cl. H01R 12/57; H01R 12/53

(52) U.S. Cl. CPC H01R 12/57; H01R 12/53

(57) ABSTRACT

An electronic device includes a circuit board, a wire, and a terminal that is disposed on the circuit board and electrically connects the circuit board and the wire. The terminal integrally includes a positional displacement prevention part that prevents positional displacement of the wire with respect to the terminal, and the terminal and the wire are bonded by a bonding part.

### CROSS REFERENCE TO RELATED APPLICATIONS

This application is a National Stage of International Application No. PCT/JP2023/018552 filed May 18, 2023, claiming priority based on Japanese Patent Application No. 2022-086796 filed May 27, 2022, the entire contents of which are incorporated in their entirety.

### TECHNICAL FIELD

The present disclosure relates to an electronic device, and particularly to an electronic device including a wire, a circuit board, and a terminal disposed on the circuit board.

### BACKGROUND ART

Conventionally, a connector for a circuit board that electrically connects a wire and a terminal disposed on the circuit board is known. Such a connector for a circuit board is disclosed in, for example, JP 2015-72824 A.

JP 2015-72824 A discloses a connector for a circuit board, including a crimp terminal attached to a wire and a housing into which the crimp terminal is inserted. The crimp terminal has a lead part that protrudes from the housing when inserted into the housing. Then, the wire and the terminal disposed on the circuit board are electrically connected by solder-bonding the lead part of the crimp terminal to the terminal disposed on the circuit board.

The housing of the connector for a circuit board described in JP 2015-72824 A is provided with a positioning pin. Then, the housing is positioned with respect to the circuit board by inserting the positioning pin of the housing into a positioning hole of the circuit board. This positioning prevents positional displacement of the lead part of the crimp terminal with respect to the terminal disposed on the circuit board.

### CITATIONS LIST

### Patent Literature

Patent Literature 1: JP 2015-72824 A

### SUMMARY OF DISCLOSURE

### Technical Problems

However, in the connector for a circuit board described in JP 2015-72824 A, while positional displacement of the lead part of the crimp terminal with respect to the terminal disposed on the circuit board can be prevented, in order to electrically connect the terminal disposed on the circuit board and the wire, it is necessary to attach the crimp terminal to the wire, then insert the crimp terminal into the housing, and solder-bond the lead part of the crimp terminal to the terminal disposed on the circuit board. Therefore, there is a problem that a step of connecting the wire to the terminal is complicated, and the number of components necessary for connecting the wire to the terminal increases for the housing and the crimp terminal.

The present disclosure has been made to solve the above problems, and provides an electronic device capable of simplifying a step of connecting a wire to a terminal while suppressing an increase in the number of components for connecting the wire to the terminal.

### Solutions to Problems

In order to achieve the above, an electronic device according to one aspect of the present disclosure includes a circuit board, a wire, and a terminal that is disposed on the circuit board and electrically connects the circuit board and the wire, in which the terminal integrally includes a positional displacement prevention part that prevents displacement of the wire with respect to the terminal, and the terminal and the wire are bonded by a bonding part. The wire is a member (electric wire) including a conductor that transmits power, and is a broad concept including an electric wire including only a conductor, an electric wire (insulated electric wire) in which the conductor is coated with an insulator, an electric wire (cable) in which an insulated electric wire is further protected by a protective coating, and the like.

In the electronic device according to one aspect of the present disclosure, as described above, the terminal integrally includes the positional displacement prevention part that prevents positional displacement of the wire with respect to the terminal. As a result, when the terminal and the wire are bonded by the bonding part, the wire can be directly bonded to the terminal while the positional displacement of the wire with respect to the terminal is prevented by the positional displacement prevention part of the terminal. Consequently, a step of connecting the wire to the terminal can be simplified as compared with a case where a crimp terminal is attached to the wire, then the crimp terminal is inserted into the housing, and the lead part of the crimp terminal is solder-bonded to the terminal disposed on the circuit board. In addition, since the terminal integrally includes the positional displacement prevention part, an increase in the number of components for connecting the wire to the terminal can be suppressed as compared with a case where a member for preventing the positional displacement of the wire with respect to the terminal is separately provided. As a result, it is possible to simplify the step of connecting the wire to the terminal while suppressing an increase in the number of components for connecting the wire W to the terminal.

In the electronic device according to the one aspect, the positional displacement prevention part is preferably formed so as to surround at least a part of an outer periphery of the wire.

In this configuration, the positional displacement prevention part surrounds at least a part of the outer periphery of the wire, and the positional displacement of the wire can be effectively suppressed.

In the electronic device according to the one aspect, the circuit board preferably includes a positioning notch that is provided at an end of the circuit board and positions the wire or the terminal with respect to the circuit board.

In this configuration, since the wire or the terminal can be positioned with respect to the circuit board by the positioning notch provided at the end of the circuit board, an increase in the number of components and complication of the structure can be suppressed as compared with a case where a member for positioning the wire or the terminal with respect to the circuit board is provided separately from the circuit board.

In the configuration in which the circuit board has the positioning notch, the wire is preferably positioned in a curved state by the positioning notch.

In this configuration, since the wire is disposed in a curved state at the positioning notch, it is possible to suppress the wire from being pulled so as to be separated from the terminal near the positioning notch. As a result, it is possible to suppress application of tensile stress to the bonding part where the terminal and the wire are bonded.

The electronic device according to the one aspect preferably further includes a resin sealing member that resin-seals the circuit board, the terminal, and the wire, and a vibration absorbing member having an insertion hole into which the wire extending from an inside of the resin sealing member to an outside of the resin sealing member is inserted, the vibration absorbing member being attached to the resin sealing member and allows vibration to be absorbed.

In this configuration, since the circuit board, the terminal, and the wire are resin-sealed by the resin sealing member, the circuit board, the terminal, and the wire can be waterproofed and dustproofed. Since the wire extending from the inside to the outside of the resin sealing member is inserted into the insertion hole of the vibration absorbing member, even when the electronic device vibrates, the vibration is absorbed by the vibration absorbing member. As a result, it is possible to prevent the wire from being worn and disconnected due to friction caused by vibration of the electronic device.

In the electronic device according to the one aspect, the terminal includes a first terminal having a stepped shape and a second terminal connected to the first terminal and connected to the circuit board, the second terminal is connected to one end side of the first terminal having the stepped shape, and the positional displacement prevention part is provided on another end side of the first terminal having the stepped shape.

In this configuration, by bonding the wire to the first terminal, the wire can be connected to the circuit board via the second terminal connected to the circuit board and the first terminal to which the second terminal is connected on one end side. Thus, by bonding the wire to the other end side of the first terminal having a stepped shape, the position to which the wire is bonded can be changed to a position separated from the second terminal connected to the circuit board. As a result, even when it is necessary to change the position to which the wire is bonded to the position separated from the second terminal in accordance with the arrangement of the device to be connected, the position to which the wire is bonded can be easily changed. As a result, the device to be connected and the wire can be easily connected. The positional displacement prevention part provided on the other end side of the first terminal can prevent the positional displacement of the wire with respect to the first terminal when the wire is bonded to the first terminal.

In the electronic device according to the one aspect, in the positional displacement prevention part of the terminal, the terminal and the wire are preferably bonded by the bonding part.

In this configuration, when the work of bonding the terminal and the wire is performed, the position where the wire is bonded to the terminal (the position of the bonding part) can be prevented from being displaced by the positional displacement prevention part of the terminal.

In the electronic device according to one aspect of the present disclosure, the following configuration is also conceivable.

### (Supplement 1)

In the configuration in which the circuit board has the positioning notch, the wire includes a plurality of wires, and the terminal having the positional displacement prevention part and the positioning notch provided on the circuit board are provided corresponding to each of the plurality of wires.

In this configuration, since each of the plurality of wires can be positioned by the positioning notch provided in the circuit board corresponding to each of the plurality of wires, an increase in the number of components and complication of the structure can be suppressed as compared with a case where a member for positioning is provided separately from the circuit board.

### (Supplement 2)

In the configuration in which the terminal includes the first terminal and the second terminal, the wire is disposed so as to extend along a direction orthogonal to a surface of the circuit board to which the second terminal is connected, and a positional displacement prevention part is formed on the other end side of the first terminal so as to extend along the wire.

In this configuration, since the wire is disposed so as to extend along the direction orthogonal to the surface of the circuit board, the wire can be pulled out in a direction orthogonal to the surface of the circuit board without bending the wire. As a result, even when the device to be connected is disposed with respect to the circuit board in a direction orthogonal to the surface of the circuit board, the device to be connected and the wire can be easily connected. In addition, on the other end side of the first terminal, the positional displacement of the wire with respect to the first terminal can be prevented by the positional displacement prevention part formed so as to extend along the wire.

### BRIEF DESCRIPTION OF DRAWINGS

FIG. 1 is a perspective view showing an electronic device according to a first embodiment.

FIG. 2 is a perspective view showing a circuit board and a terminal of the electronic device according to the first embodiment.

FIG. 3 is a partially enlarged view in which a periphery of the terminal according to the first embodiment is enlarged.

FIG. 4 is a perspective view showing a terminal according to the first embodiment.

FIG. 5 is a perspective view showing attachment of a wire according to the first embodiment.

FIG. 6 is a sectional view showing bonding of the wire and the terminal according to the first embodiment.

FIG. 7 is a sectional view showing the electronic device according to the first embodiment.

FIG. 8 is a perspective view showing an electronic device according to a second embodiment.

FIG. 9 is a perspective view showing a circuit board and a terminal of the electronic device according to the second embodiment.

FIG. 10 is a perspective view showing attachment of a first terminal according to the second embodiment.

FIG. 11 is a perspective view showing the first terminal according to the second embodiment.

FIG. 12 is a partially enlarged view in which a periphery of a second terminal according to the second embodiment is enlarged.

FIG. 13 is a first diagram for describing an assembly step of the electronic device according to the second embodiment.

FIG. 14 is a second diagram for describing the assembly step of the electronic device according to the second embodiment.

FIG. 15 is a third diagram for describing the assembly step of the electronic device according to the second embodiment.

FIG. 16 is a sectional view showing the electronic device according to the second embodiment.

### DESCRIPTION OF EMBODIMENTS

Hereinafter, embodiments will be described with reference to the drawings.

### First Embodiment

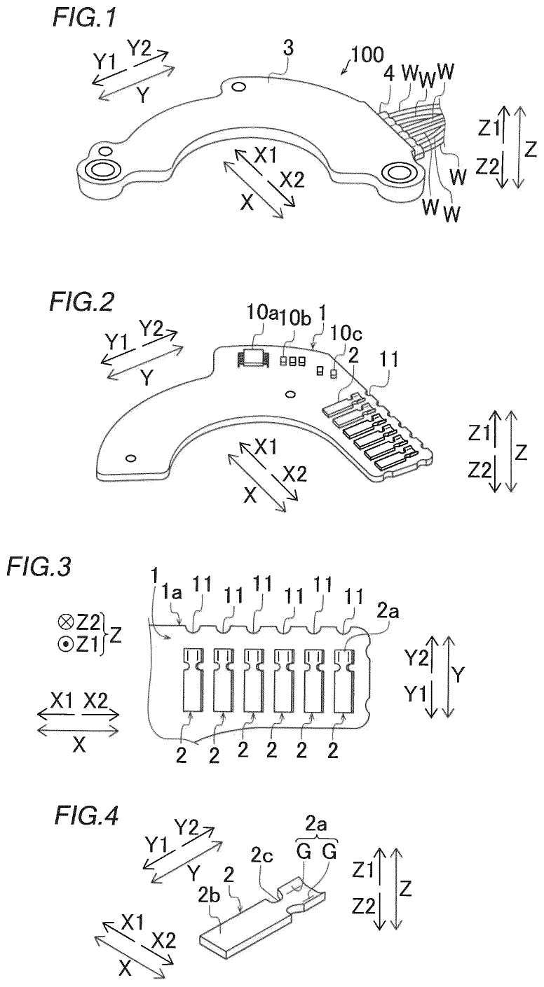

An electronic device according to a first embodiment will be described with reference to FIGS. 1 to 7.

### (Overall Configuration of Electronic Device)

As shown in FIG. 1, an electronic device 100 includes a plurality of wires W. The electronic device 100 includes a resin sealing member 3 that resin-seals the wires W, and a circuit board 1 and a terminal 2 (see FIG. 2) to be described later. The electronic device 100 is, for example, a device for a vehicle. Specifically, the electronic device 100 is a device that performs signal processing of a sensor that detects a state of a motor of the vehicle. Note that the electronic device 100 may be an electronic control unit (ECU) for a vehicle.

As shown in FIG. 1, the electronic device 100 includes a grommet 4. The grommet 4 is attached to the resin sealing member 3. The grommet 4 is a member capable of absorbing vibration. The grommet 4 includes, for example, acrylic rubber. Note that the grommet 4 is an example of a “vibration absorbing member” in the claims.

As shown in FIG. 2, the electronic device 100 includes the circuit board 1 and the terminal 2 disposed on the circuit board 1. The circuit board 1 is a printed circuit board (PCB) on which a wiring pattern is formed by a conductor. Electronic components such as a signal processing integrated circuit (IC) 10a, a diode 10b, and a capacitor 10c are mounted on the circuit board 1. The terminal 2 is mounted on the circuit board 1 by reflow solder. The terminal 2 is electrically connected to a conductor pattern of the circuit board 1. The terminal 2 is a conductive member. The terminal 2 includes, for example, brass. The terminal 2 electrically connects the circuit board 1 and the wire W.

### (Notch)

As shown in FIG. 3, the circuit board 1 is provided at an end 1a of the circuit board 1 and has a notch 11 that positions the wire W with respect to the circuit board 1. The notch 11 is formed so as to cut out the end 1a of the circuit board 1 in a semicircular shape when viewed from a Z1 direction side. Note that the notch 11 is an example of a “positioning notch” in the claims.

A plurality of (six) notches 11 are provided at the end 1a of the circuit board 1. A plurality of (six) terminals 2 are mounted on the circuit board 1. The notch 11 is provided at a position on a Y2 direction side with respect to the terminal 2. The notch 11 is provided at a position corresponding to the terminal 2 in an X direction.

(Positional Displacement Prevention Part)

As shown in FIG. 4, the terminal 2 includes a positional displacement prevention part 2a that prevents positional displacement of the wire W with respect to the terminal 2. The terminal 2 has a flat part 2b extending along a Y direction. The terminal 2 integrally includes the positional displacement prevention part 2a. Specifically, the positional displacement prevention part 2a is formed integrally with the flat part 2b on the Y2 direction side of the flat part 2b. As shown in FIG. 4, the positional displacement prevention part 2a includes a pair of guides G. The guide G is formed so as to warp from a Z2 direction side toward the Z1 direction side. The positional displacement prevention part 2a has a U-shape when viewed from a Y1 direction side. The terminal 2 is molded by press working. A constricted part 2c having a smaller width in the X direction than the flat part 2b is provided between the positional displacement prevention part 2a and the flat part 2b. As a result, bending work of the positional displacement prevention part 2a (guide G) can be more easily performed than in a case where the constricted part 2c is not provided.

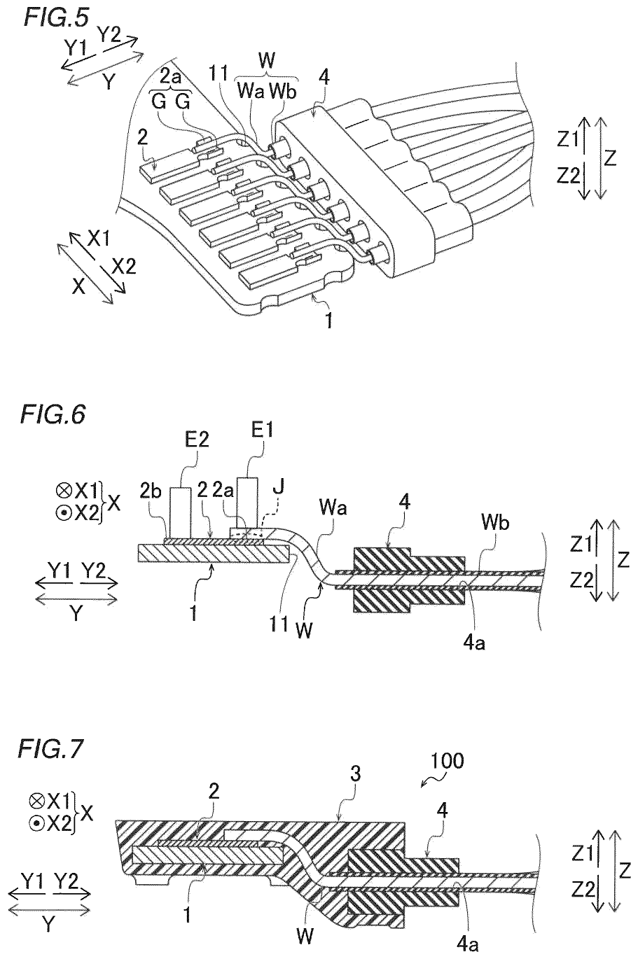

As shown in FIG. 5, the terminal 2 having the positional displacement prevention part 2a is provided corresponding to each of the plurality of wires W. In the first embodiment, a plurality of (six) terminals 2 are provided corresponding to a plurality of (six) wires W. The wire W includes a conductor line Wa including a plurality of linear conductors and an insulation film Wb covering the conductor line Wa. When resin-sealing the circuit board 1, the terminal 2, and the wire W with the resin sealing member 3, the notch 11 holds the conductor line Wa of the wire W disposed so as to be caught inside the notch 11.

The notch 11 provided in the circuit board 1 is provided corresponding to each of the plurality of wires W. As a result, since each of the plurality of wires W can be positioned by the notch 11 provided in the circuit board 1 corresponding to each of the plurality of wires W, an increase in the number of components and complication of the structure can be suppressed as compared with a case where a member for positioning is provided separately from the circuit board 1.

The positional displacement prevention part 2a is formed so as to surround a part of an outer periphery of the wire W bonded to the terminal 2. Specifically, as shown in FIG. 5, the conductor line Wa of the wire W and the terminal 2 are bonded in a state where the conductor line Wa of the wire W is disposed such that the conductor line Wa is sandwiched between the pair of guides G in the X direction. That is, the conductor line Wa of the wire W and the terminal 2 are bonded to each other at a position sandwiched between the pair of guides G of the positional displacement prevention part 2a in the X direction. Therefore, when the conductor line Wa of the wire W and the terminal 2 are bonded, the conductor line Wa of the wire W can be bonded to the terminal 2 while the positional displacement of the conductor line Wa of the wire W toward an X1 direction side and an X2 direction side is prevented by the pair of guides G of the positional displacement prevention part 2a. Thus, the positional displacement of the wire W can be effectively suppressed.

In addition, in the positional displacement prevention part 2a of the terminal 2, the terminal 2 and the wire W are bonded by a bonding part J (see FIG. 6). Specifically, a welding electrode E2 is pressed against the flat part 2b of the terminal 2 while the conductor line Wa of the wire W is pressed against the positional displacement prevention part 2a of the terminal 2 by a welding electrode E1. Then, a current flows between the welding electrode E1 and the welding electrode E2. As a result, resistance welding in which welding is performed by using heat (Joule heat) generated by contact resistance is performed between the conductor line Wa of the wire W and the terminal 2.

### (Configuration Related to Grommet and Resin Sealing Member)

As shown in FIG. 6, the grommet 4 has an insertion hole 4a into which the wire W extending from the inside of the resin sealing member 3 to the outside of the resin sealing member 3 is inserted. The wire W is joined to the terminal 2 in a state of being inserted into the insertion hole 4a of the grommet 4 and positioned with respect to the terminal 2 of the circuit board 1 by the notch 11. As shown in FIG. 7, the grommet 4 is resin-sealed by the resin sealing member 3 so as to be partially exposed on the Y2 direction side. The grommet 4 is resin-sealed by the resin sealing member 3 together with the circuit board 1, the terminal 2, and the wire W. The resin sealing member 3 is a resin having an insulating property. At the time of molding, the resin sealing member 3 is cut off at the grommet 4 by a molding die. The insertion hole 4a of the grommet 4 is disposed on the Z2 direction side with respect to the circuit board 1. The wire W is disposed in a curved state at a portion resin-sealed by the resin sealing member 3 between the terminal 2 and the insertion hole 4a of the grommet 4. That is, the wire W is positioned in a curved state by the notch 11. Specifically, the wire W is disposed in a Z shape at a portion resin-sealed by the resin sealing member 3 when viewed from the X2 direction side.

### (Effects of First Embodiment)

In the first embodiment, the following effects can be obtained.

In the first embodiment, as described above, the terminal 2 integrally includes the positional displacement prevention part 2a that prevents positional displacement of the wire W with respect to the terminal 2. As a result, when the terminal 2 and the wire W are bonded by the bonding part J, the wire W can be directly bonded to the terminal 2 while the positional displacement of the wire W with respect to the terminal 2 is prevented by the positional displacement prevention part 2a of the terminal 2. Consequently, a step of connecting the wire W to the terminal 2 can be simplified as compared with a case where a crimp terminal is attached to the wire W, then the crimp terminal is inserted into the housing, and the lead part of the crimp terminal is solder-bonded to the terminal 2 disposed on the circuit board 1. In addition, since the terminal 2 integrally includes the positional displacement prevention part 2a, an increase in the number of components for connecting the wire W to the terminal 2 can be suppressed as compared with a case where a member for preventing the positional displacement of the wire W with respect to the terminal 2 is separately provided. As a result, it is possible to simplify the step of connecting the wire W to the terminal 2 while suppressing an increase in the number of components for connecting the wire W to the terminal 2.

In the first embodiment, as described above, the positional displacement prevention part 2a is formed so as to surround at least a part of the outer periphery of the wire W. Thus, the positional displacement prevention part 2a surrounds at least a part of the outer periphery of the wire W, and the positional displacement of the wire W can be effectively suppressed.

In the first embodiment, as described above, the circuit board 1 is provided at the end 1a of the circuit board 1 and has the notch 11 that positions the wire W with respect to the circuit board 1. Thus, since the wire W can be positioned with respect to the circuit board 1 by the notch 11 provided at the end 1a of the circuit board 1, an increase in the number of components and complication of the structure can be suppressed as compared with a case where a member for positioning the wire W with respect to the circuit board 1 is provided separately from the circuit board 1.

In the first embodiment, as described above, the wire W is positioned in a curved state by the notch 11 (positioning notch). Thus, since the wire W is disposed in a curved state at the notch 11, it is possible to suppress the wire W from being pulled so as to be separated from the terminal 1a near the notch 11. As a result, it is possible to suppress application of tensile stress to the bonding part J where the terminal 1a and the wire W are bonded.

In the first embodiment, as described above, the electronic device 100 includes the circuit board 1, the terminal 2, and the resin sealing member 3 that resin-seals the wire W. Thus, since the circuit board 1, the terminal 2, and the wire W are resin-sealed by the resin sealing member 3, the circuit board 1, the terminal 2, and the wire W can be waterproofed and dustproofed. The electronic device 100 includes the insertion hole 4a into which the wire W extending from the inside of the resin sealing member 3 to the outside of the resin sealing member 3 is inserted, and the grommet 4 attached to the resin sealing member 3 and capable of absorbing vibration. Thus, since the wire W extending from the inside to the outside of the resin sealing member 3 is inserted into the insertion hole 4a of the grommet 4, even when the electronic device 100 vibrates, the vibration is absorbed by the grommet 4. As a result, it is possible to prevent the wire W from being worn and disconnected due to friction caused by vibration of the electronic device 100.

In the first embodiment, as described above, in the positional displacement prevention part 2a of the terminal 2, the terminal 2 and the wire W are bonded by the bonding part J. Thus, when the work of bonding the terminal 2 and the wire W is performed, the position where the wire W is bonded to the terminal 2 (the position of the bonding part J) can be prevented from being displaced by the positional displacement prevention part 2a of the terminal 2.

### Second Embodiment

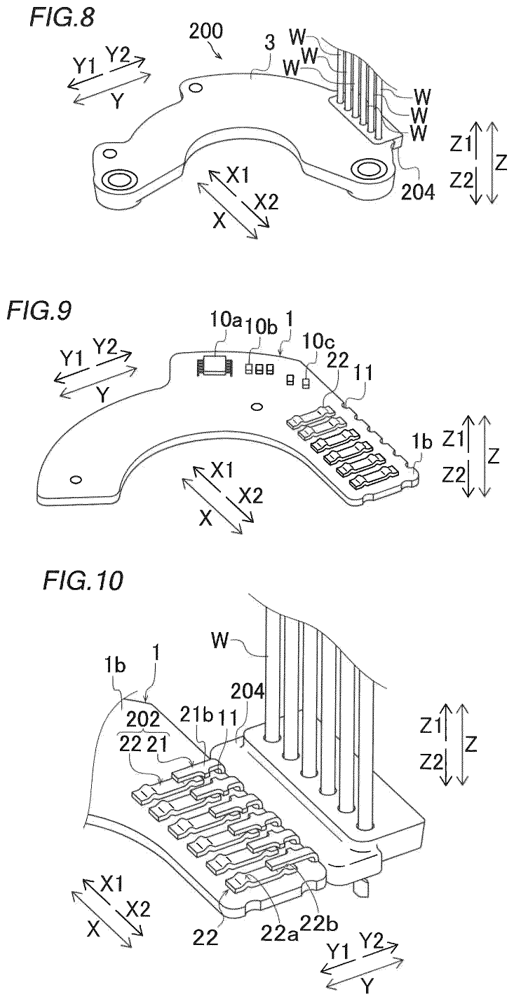

An electronic device 200 according to a second embodiment of the present disclosure will be described with reference to FIGS. 8 to 16. Similar components to the components of the first embodiment are denoted by the same reference signs, and the description thereof will be omitted.

### (Overall Configuration of Electronic Device)

As shown in FIG. 8, in the electronic device 200, the wire W is disposed so as to extend from a grommet 204 toward the Z1 direction side. Similarly to the electronic device 100 according to the first embodiment, the resin sealing member 3 resin-seals the wire W, the circuit board 1 (the signal processing IC 10a, the diode 10b, the capacitor 10c (see FIG. 9), and the like), and a terminal 202. Note that the grommet 204 is an example of a “vibration absorbing member” in the claims.

As shown in FIG. 10, in the electronic device 200, the wire W is disposed so as to extend along a Z direction orthogonal to a surface 1b (XY plane) of the circuit board 1. Thus, since the wire W is disposed so as to extend along the Z direction orthogonal to the surface 1b of the circuit board 1, the wire W can be pulled out in the Z direction without bending the wire W. As a result, even when the device to be connected is disposed in the Z direction with respect to the circuit board 1, the device to be connected and the wire W can be easily connected.

(Configuration of terminal)

As shown in FIG. 10, the electronic device 200 includes the terminal 202 including a first terminal 21 and a second terminal 22. The second terminal 22 is connected to the first terminal 21 and is connected to the circuit board 1. The second terminal 22 has protrusions 22a and 22b that are curved so as to protrude toward the Z1 direction side. The welding electrode E1 (see FIG. 6) abuts on the protrusion 22a when the first terminal 21 and the second terminal 22 are resistance-welded. The first terminal 21 abuts on the protrusion 22b when the first terminal 21 and the second terminal 22 are resistance-welded. That is, the first terminal 21 and the second terminal 22 are bonded at the protrusion 22b of the second terminal 22.

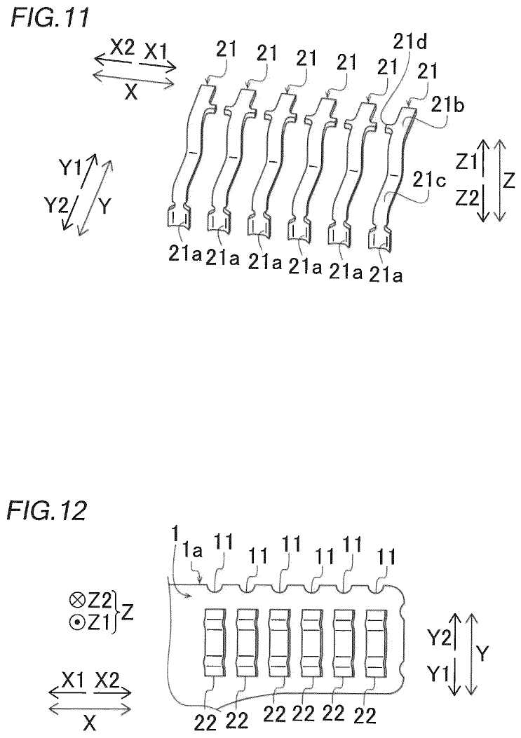

As shown in FIG. 11, the first terminal 21 has a stepped shape including an upper step 21b and a lower step 21c. The second terminal 22 is connected to one end side (Y1 direction side) of the first terminal 21. Specifically, as shown in FIG. 10, the second terminal 22 is connected to the upper step 21b of the first terminal 21. As shown in FIG. 11, a positional displacement prevention part 21a is provided on the other end side (Z2 direction side) of the first terminal 21. Specifically, a positional displacement prevention part 21a is formed so as to extend from the lower step 21c toward the Z2 direction side. In the second embodiment, the plurality of (six) first terminals 21 are integrally molded, and are divided into six first terminals 21 by disconnecting a coupling part 21d. The first terminals 21 is disconnected after the wire W is bonded to the first terminal 21 and before the first terminal 21 is bonded to the second terminal 22.

As shown in FIG. 12, the circuit board 1 is provided at the end 1a of the circuit board 1 and has the notch 11 that positions the first terminal 21 with respect to the circuit board 1. The notch 11 is provided at a position on the Y2 direction side with respect to the second terminal 22. The notch 11 is provided at a position corresponding to the second terminal 22 in an X direction.

### (Assembly of Electronic Device)

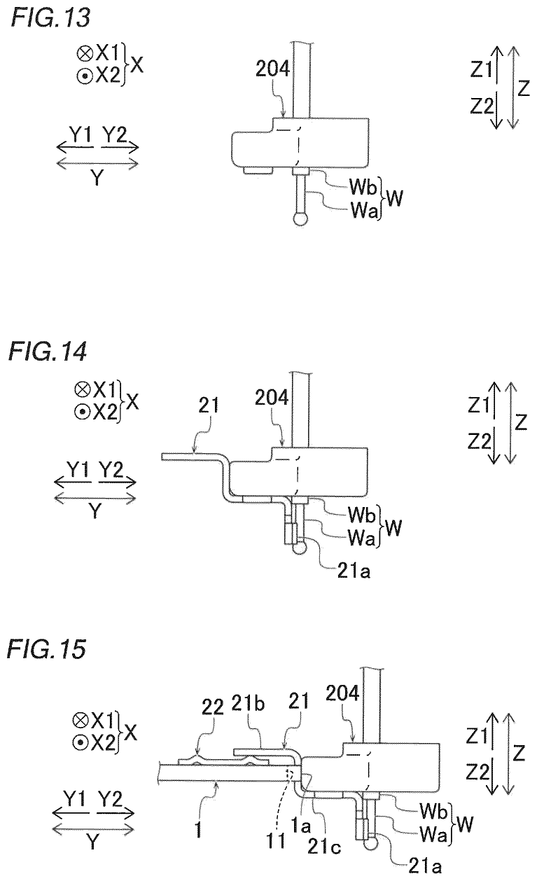

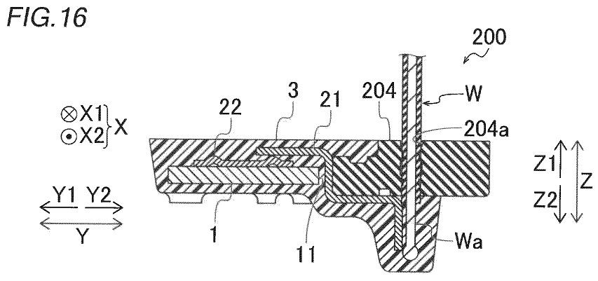

As shown in FIG. 13, in an assembly of the electronic device 200, first, the wire W is inserted into the grommet 204. The wire W is inserted into an insertion hole 204a (see FIG. 16) of the grommet 204.

Then, as shown in FIG. 14, the first terminal 21 and the wire W are bonded by resistance welding. Specifically, the conductor line Wa of the wire W is bonded by resistance welding at the positional displacement prevention part 21a of the first terminal 21. As shown in FIG. 15, the positional displacement prevention part 21a is disposed on the Z2 direction side with respect to the circuit board 1. That is, the first terminal 21 is resistance-welded to the wire W on the Z2 direction side of the circuit board 1.

In the second embodiment, the positional displacement prevention part 2a is formed so as to extend along the wire W on the other end side (Z2 direction side) of the first terminal 21. Thus, on the other end side of the first terminal 21, the positional displacement prevention part 21a can prevent the positional displacement of the wire W with respect to the first terminal 21.

Then, as shown in FIG. 15, the second terminal 22 mounted on the circuit board 1 and the first terminal 21 are resistance-welded. The first terminal 21 is resistance-welded to the second terminal 22 on the Z1 direction side of the circuit board 1. In the second embodiment, the first terminal 21 and the second terminal 22 are resistance-welded in a state where the grommet 204 is pressed against the end 1a of the circuit board 1. Then, after the first terminal 21 and the second terminal 22 are resistance-welded, the circuit board 1, the first terminal 21, the second terminal 22, the wire W, and the grommet 204 are resin-sealed by the resin sealing member 3. As shown in FIG. 16, the first terminal 21 is disposed so as to be sandwiched between the notch 11 of the circuit board 1 and the grommet 204. The grommet 204 is resin-sealed by the resin sealing member 3 so as to be partially exposed on the Y2 direction side.

Other configurations of the second embodiment are similar to the configurations of the first embodiment.

### (Effects of Second Embodiment)

In the second embodiment, the following effects can be obtained.

In the second embodiment, as in the first embodiment, it is possible to simplify the step of connecting the wire W to the terminal 2 while suppressing an increase in the number of components for connecting the wire W to the terminal 2.

In the second embodiment, as described above, the circuit board 1 is provided at the end 1a of the circuit board 1 and has the notch 11 that positions the first terminal 21 with respect to the circuit board 1. Thus, since the second terminal 22 can be positioned with respect to the circuit board 1 by the notch 11 provided at the end 1a of the circuit board 1, an increase in the number of components and complication of the structure can be suppressed as compared with a case where a member for positioning the second terminal 22 with respect to the circuit board 1 is provided separately from the circuit board 1.

In the second embodiment, as described above, the terminal 2 includes the first terminal 21 having a stepped shape and the second terminal 22 connected to the first terminal 21 and connected to the circuit board 1. The second terminal 22 is connected to one end side of the first terminal 21 having a stepped shape, and the positional displacement prevention part 21a is provided on the other end side of the first terminal 21 having a stepped shape. Thus, by bonding the wire W to the first terminal 21, the wire W can be connected to the circuit board 1 via the second terminal 22 connected to the circuit board 1 and the first terminal 21 to which the second terminal 22 is connected on one end side. Thus, by bonding the wire W to the other end side of the first terminal 21 having a stepped shape, the position to which the wire W is bonded can be changed to a position separated from the second terminal 22 connected to the circuit board 1. As a result, even when it is necessary to change the position to which the wire W is bonded to the position separated from the second terminal 22 in accordance with the arrangement of the device to be connected, the position to which the wire W is bonded can be easily changed. As a result, the device to be connected and the wire W can be easily connected. The positional displacement prevention part 21a provided on the other end side of the first terminal 21 can prevent the positional displacement of the wire W with respect to the first terminal 21 when the wire W is bonded to the first terminal 21.

Other effects of the second embodiment are similar to the effects of the first embodiment.

### [Modifications]

It should be understood that the embodiments disclosed herein are illustrative in all respects and not restrictive. The scope of the present disclosure is defined not by the description of the above embodiments but by the claims, and further includes meanings equivalent to the claims and all changes (modifications) within the scope.

For example, in the first embodiment, an example in which the terminal 2 and the wire W are bonded by resistance welding has been described, but the present disclosure is not limited to this example. In the present disclosure, the terminal and the wire may be bonded by solder bonding.

In addition, in the first embodiment, an example in which the electronic device 100 is a device for a vehicle has been described, but the present disclosure is not limited to this example. In the present disclosure, the electronic device is not limited to a device for a vehicle as long as the device includes a circuit board, a wire, and a terminal.

In the first embodiment, an example has been described in which the terminal 2 and the wire W are bonded by the bonding part J in the positional displacement prevention part 2a of the terminal 2, but the present disclosure is not limited to this example. In the present disclosure, the terminal and the wire may be bonded to each other by a bonding part at a portion other than the positional displacement prevention part.

In the first embodiment, an example has been described in which the circuit board 1 is provided at the end 1a of the circuit board 1, and includes the notch 11 (positioning notch) for positioning the wire W with respect to the circuit board 1. However, the present disclosure is not limited to this example. In the present disclosure, a member for positioning the wire with respect to the circuit board may be provided separately from the circuit board.

In the second embodiment, an example has been described in which the circuit board 1 is provided at the end 1a of the circuit board 1, and includes the notch 11 (positioning notch) for positioning the first terminal 21 with respect to the circuit board 1. However, the present disclosure is not limited to this example. In the present disclosure, a member for positioning the terminal with respect to the circuit board may be provided separately from the circuit board.

In the first embodiment, an example has been described in which the electronic device 100 includes the circuit board 1, the terminal 2, and the resin sealing member 3 that resin-seals the wire W, but the present disclosure is not limited to this example. In the present disclosure, the electronic device is not required to include the circuit board, the terminal, and the resin sealing member that resin-seals the wire. That is, the circuit board, the terminal, and the wire are not required to be resin-sealed.

In the first embodiment, an example has been described in which the electronic device 100 includes the insertion hole 4a into which the wire W extending from the inside of the resin sealing member 3 to the outside of the resin sealing member 3 is inserted, and the grommet 4 (vibration absorbing member) attached to the resin sealing member 3 and capable of absorbing vibration. However, the present disclosure is not limited to this example. In the present disclosure, the electronic device is not required to include the resin sealing member and the vibration absorbing member.

In the first embodiment, an example has been described in which the wire W is disposed in a curved state (that is, the wire W is positioned in a curved state by the notch 11 (positioning notch)) at a portion resin-sealed by the resin sealing member 3 between the terminal 2 and the insertion hole 4a of the grommet 4 (vibration absorbing member). However, the present disclosure is not limited to this example. In the present disclosure, the wire may be disposed in a straight state at a portion resin-sealed by the resin sealing member between the terminal and the insertion hole of the vibration absorbing member (that is, the wire may be positioned by the positioning notch in a straight state).

In the second embodiment, an example has been described in which the terminal 2 includes the first terminal 21 and the second terminal 22 connected to the first terminal 21 and connected to the circuit board 1, but the present disclosure is not limited to this example. In the present disclosure, the circuit board and the wire may be electrically connected via three or more terminals.

In the second embodiment, an example has been described in which the terminal 2 includes the first terminal 21 having a stepped shape, but the present disclosure is not limited to this example. In the present disclosure, the first terminal may be a terminal having an L shape.

In the first embodiment, an example has been described in which the positional displacement prevention part 2a is formed so as to surround a part of the outer periphery of the wire W bonded to the terminal 2, but the present disclosure is not limited to this example. In the present disclosure, the positional displacement prevention part may have a tubular shape so as to surround the entire periphery of the outer periphery of the wire bonded to the terminal.

In the first embodiment, an example has been described in which the notch 11 (positioning notch) provided in the circuit board 1 is provided corresponding to each of the plurality of wires W, but the present disclosure is not limited to this example. In the present disclosure, the positioning notch provided in the circuit board may be provided only for any of the plurality of wires.

### REFERENCE SIGNS LIST

1: Circuit board,

1a: End (of circuit board),

1b: Surface,

2, 202: Terminal,

2a, 21a: Positional displacement prevention part,

3: Resin sealing member,

4, 204: Grommet (vibration absorbing member),

4a, 204a: Insertion hole,

11: Notch (positioning notch),

21: First terminal,

22: Second terminal,

100, 200: Electronic device,

J: Bonding part, and

W: Wire

1. An electronic device comprising:
a circuit board;
a wire; and
a terminal that is disposed on the circuit board and electrically connects the circuit board and the wire, wherein
the terminal integrally includes a positional displacement prevention part that prevents displacement of the wire with respect to the terminal, and the terminal and the wire are bonded by a bonding part.

2. The electronic device according to claim 1, wherein the positional displacement prevention part is formed so as to surround at least a part of an outer periphery of the wire.

3. The electronic device according to claim 1, wherein the circuit board includes a positioning notch that is provided at an end of the circuit board and positions the wire or the terminal with respect to the circuit board.

4. The electronic device according to claim 3, wherein the wire is positioned in a curved state by the positioning notch.

5. The electronic device according to claim 1, further comprising:
a resin sealing member that resin-seals the circuit board, the terminal, and the wire; and
a vibration absorbing member having an insertion hole into which the wire extending from an inside of the resin sealing member to an outside of the resin sealing member is inserted, the vibration absorbing member being attached to the resin sealing member and allows vibration to be absorbed.

6. The electronic device according to claim 1, wherein
the terminal includes a first terminal having a stepped shape and a second terminal connected to the first terminal and connected to the circuit board,
the second terminal is connected to one end side of the first terminal having the stepped shape, and
the positional displacement prevention part is provided on another end side of the first terminal having the stepped shape.

7. The electronic device according to claim 1, wherein the terminal and the wire are bonded by the bonding part at the positional displacement prevention part of the terminal.
